(19) United States
(12) Patent Application Publication
(10) Pub. No.: US 2024/0404988 A1
(43) Pub. Date: Dec. 5, 2024

(54) FLUXLESS DIE BONDING USING IN-SITU PLASMA TREATMENT AND APPARATUS FOR EFFECTING THE SAME

(71) Applicant: Taiwan Semiconductor Manufacturing Company Limited, Hsinchu (TW)

(72) Inventors: Hui-Min Huang, Taoyuan City (TW); Kai Jun Zhan, Taoyuan City (TW); Ming-Da Cheng, Taoyuan (TW); Chih-Yuan Chiu, Zhudong Township (TW); Amram Eitan, Hsinchu (TW)

(21) Appl. No.: 18/327,908

(22) Filed: Jun. 2, 2023

(51) Int. Cl. H01L 23/00; H01J 37/32

(52) U.S. Cl. CPC H01L 24/81; H01J 37/3244; H01J 37/32816; H01L 24/75; H01L 24/97; H01J 2237/335; H01L 2224/7501; H01L 2224/75252; H01L 2224/75301; H01L 2224/7565; H01L 2224/7598; H01L 2224/81013; H01L 2224/81022; H01L 2224/81191; H01L 2224/81203; H01L 2224/81234; H01L 2224/81815; H01L 2224/97; H01L 2924/20102; H01L 2924/20103

(57) ABSTRACT

A bonded assembly may be formed by providing at least a first packaging substrate in a low-oxygen ambient; providing at least a first semiconductor package in the low-oxygen ambient; performing a first plasma package-treatment process on the first semiconductor package in the low-oxygen ambient by directing at least one first plasma jet to first solder material portions bonded to the first semiconductor package; and bringing the first solder material portions onto, or in proximity to, first substrate-side bonding structures located on the first packaging substrate while the at least one first plasma jet is directed to the first solder material portions. The first substrate-side bonding structures are treated with the first plasma jet. The first semiconductor package is bonded to the first packaging substrate while, or after, the first substrate-side bonding structures are treated with the first plasma jet.

### BACKGROUND

Bonding a semiconductor die to a packaging substrate typically uses flux. However, the use of flux in a bonding process may have adverse effects on the bonded assembly. For example, flux may contain impurities that may contaminate the bonding surfaces. This may lead to poor electrical performance of even device failure. Also, in instances in which the flux is not properly cleaned, flux residue may remain on bonding surfaces and cause reliability issues. The heat and pressure used during the bonding process may cause a semiconductor die or package substrate to warp and cause structural damage, leading to poor alignment and poor electrical performance. In other instances in which the bonding is not performed correctly, the semiconductor die may delaminate from the package substrate, leading to device failure. In addition, flux residue may cause corrosion, oxidation, and other reliability issues over time, reducing the lifespan of the device. Also, improper use of flux may cause poor soldering, which may lead to poor electrical performance and device failure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an exemplary bonding apparatus prior to loading a wafer and semiconductor packages according to an embodiment of the present disclosure.

FIG. 2 is a vertical cross-sectional view of the exemplary bonding apparatus after transporting a first semiconductor package to an initial first package clean position according to an embodiment of the present disclosure.

FIG. 3A is a vertical cross-sectional view of the exemplary bonding apparatus at the beginning of a first plasma treatment step of a first plasma package-treatment process according to an embodiment of the present disclosure.

FIG. 3B is a vertical cross-sectional view of an alternative configuration of the exemplary bonding apparatus at the beginning of a first plasma treatment step of a first plasma package-treatment process according to an embodiment of the present disclosure.

FIG. 4 is a vertical cross-sectional view of the exemplary bonding apparatus during a second plasma treatment step of the first plasma package-treatment process and a simultaneous first die bonding process according to an embodiment of the present disclosure.

FIG. 5 is a vertical cross-sectional view of the exemplary bonding apparatus after transporting a second semiconductor package to an initial second package clean position according to an embodiment of the present disclosure.

FIG. 6 is a vertical cross-sectional view of the exemplary bonding apparatus during a first plasma treatment step of a second plasma package-treatment process according to an embodiment of the present disclosure.

FIG. 7 is a vertical cross-sectional view of the exemplary bonding apparatus during a second plasma treatment step of the second plasma package-treatment process and a simultaneous second die bonding process according to an embodiment of the present disclosure.

FIG. 8 is a vertical cross-sectional view of the exemplary bonding apparatus during a third plasma package-treatment process and a third die bonding process according to an embodiment of the present disclosure.

FIG. 9 is a vertical cross-sectional view of the exemplary bonding apparatus during unloading of an assembly of semiconductor packages and packaging substrates according to an embodiment of the present disclosure.

FIG. 10 is a schematic top-down view of an inside of a first configuration of the exemplary bonding apparatus at a processing step of FIG. 6 according to an embodiment of the present disclosure.

FIG. 11 is a schematic top-down view of an inside of a second configuration of the exemplary bonding apparatus at a processing step of FIG. 6 according to an embodiment of the present disclosure.

FIG. 12 is a first flowchart illustrating steps for forming a bonded assembly according to an embodiment of the present disclosure.

FIG. 13 is a second flowchart illustrating steps for forming a bonded assembly according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Bonding a semiconductor die to a packaging substrate is a critical step in the manufacturing of electronic devices, as it ensures that the semiconductor die is properly connected to the packaging substrate and may function as intended. One of the most common methods for bonding a semiconductor die to a packaging substrate is by using flux. However, the use of flux may have an adverse effect of inducing structural damages to a bonded assembly. Flux is a chemical substance that is applied to the bonding surface of a semiconductor die and packaging substrate before the two are joined together. The flux is used to remove any oxides or other contaminants on the bonding surfaces, which may prevent a proper bond from forming. Additionally, flux may also act as a lubricant, making it easier to position the semiconductor die on the packaging substrate.

However, the use of flux may also have negative effects on the bonded assembly. The flux may cause structural damage to the semiconductor die and packaging substrate, especially in instances in which the flux is not properly cleaned off after the bonding process. The flux may also cause corrosion to the bonding surfaces, which may weaken the bond and make the assembly more susceptible to failure. The most common type of damage that may be caused by flux is called “die-pad cratering,” which occurs when the flux causes a corrosion in the die-pad of the packaging substrate. This corrosion may create a hole or “crater” that may weaken the bond between the die and the substrate. Another type of damage that may be caused by flux is called “die-pad delamination,” which occurs in instances in which the flux causes the die-pad to separate from the substrate. Die-pad delamination may occur in instances in which the flux is not properly cleaned off the bonding surfaces, or in instances in which the flux causes corrosion to the die-pad. Die-pad cratering and die-pad delamination may both cause a variety of problems such as electrical open circuits, and even die cracking. Generally, the use of flux may also have an adverse effect of inducing structural damages to a bonded assembly.

According to an embodiment of the present disclosure, atmospheric pressure plasma jet (APPJ) treatment may be performed to clean surface contaminants from bonding structures and solder material portions prior to performing a thermocompression bonding (TCB) process between a semiconductor die and a packaging substrate. APPJ treatment can be used in semiconductor fabrication to clean, activate and treat surfaces. APPJ uses a low-temperature plasma, generated at atmospheric pressure, to modify the surface chemistry of a material. Plasma is a state of matter that is created when a gas is ionized, or when its atoms are stripped of some of their electrons, creating mixture of ions, electrons, and neutral particles. Plasma may be created at a variety of pressures, including atmospheric pressure.

The APPJ system typically consists of a plasma generator, a gas feed system, and a nozzle that directs the plasma onto the surface to be treated. The plasma may be generated by introducing a gas, such as argon or oxygen, into the plasma generator, where it is excited by an electrical discharge. The plasma generator may create a plasma, which is then directed through the nozzle and onto the surface to be treated. APPJ may be a non-contact, low-temperature, and low-pressure process, which makes APPJ compatible with a wide range of materials and can be easily integrated into existing semiconductor fabrication processes.

The generated high-energy plasma of an APPJ system may remove contaminants and particles from surfaces, providing a clean surface for subsequent processing steps. The plasma may modify the surface chemistry of a material, increasing the reactivity of the material and making the material more suitable for subsequent processing steps. The plasma may also be used to deposit thin films or change the surface morphology of a material. The plasma may be used to remove or passivate surface oxides and other unwanted surface layers. The plasma may also be used to change the surface energy of a material to improve the adhesion of subsequent layers.

There are several factors that may contribute to the time-consuming nature of APPJ treatment. One factor is the desire for precise control of the plasma parameters, such as temperature, plasma density, and gas flow rate. These parameters should be carefully controlled in order to achieve the desired surface modification without damaging the material being treated. Such control may consume a large amount of time and attention from an operator. In addition, the material surface may further benefit from a careful cleaning and preparation before the APPJ treatment. This may include removing contaminants, roughing up the surface to improve adhesion, or applying a pre-treatment to improve the effectiveness of the plasma treatment. Sequential performance of the APPJ treatment and the bonding process for each bonded pair of a semiconductor die and a packaging substrate may be time-consuming.

According to an aspect of the present disclosure, embodiment apparatus and methods are provided for parallel execution of APPJ treatment and TCB processes over multiple pairs of a respective semiconductor die and a respective packaging substrate. A combination of a stationary plasma treatment system and a mobile plasma treatment system may be used to simultaneously provide plasma treatments on a pair of a semiconductor die and a packaging substrate, while a mobile thermocompressive bonding head performs a TCB process on another pair of a semiconductor die and a packaging substrate. The plasma treatment processes and the bonding process may be performed in a low-oxygen environment. Joint interfaces may be free of bonding line interfaces. Various embodiments disclosed herein may provide time efficient execution of APPJ treatments and TCB processes.

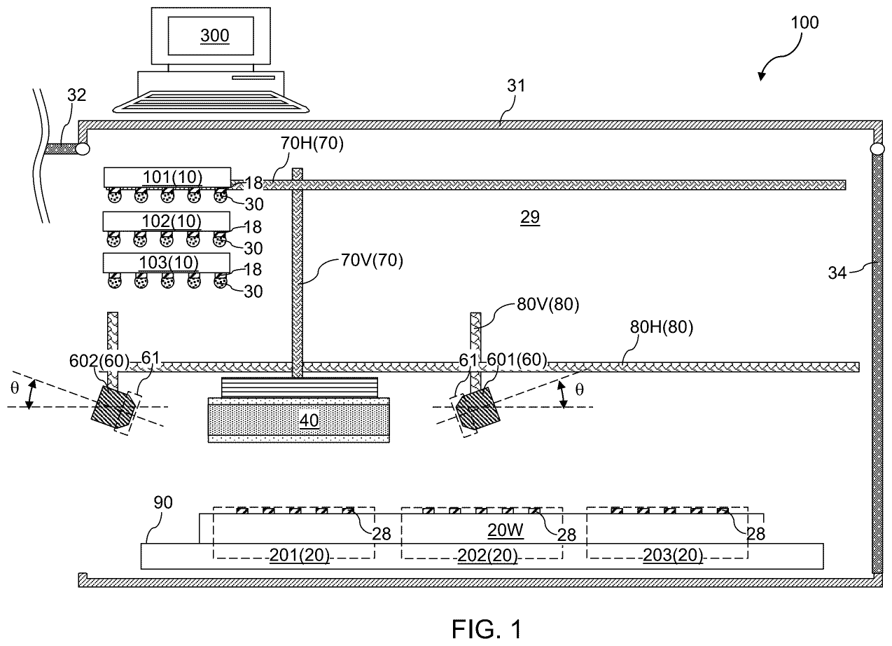

Referring to FIG. 1, an exemplary bonding apparatus 100 according to an embodiment of the present disclosure is illustrated. The exemplary bonding apparatus 100 may include a process chamber (31, 32, 34) including chamber enclosure 31 and an ambient control system configured to provide a low-oxygen ambient 29 within a volume that is spatially bounded by the chamber enclosure 31. As used herein, a “low-pressure ambient” refers to an ambient having an oxygen partial pressure that is lower than the oxygen partial pressure (of about 21.23 kPa) in a standard atmospheric condition. In one embodiment, the low-oxygen ambient 29 may have an oxygen partial pressure that is lower than about 80% of the oxygen partial pressure in standard atmospheric conditions, such as lower than 17 kPa. The total pressure of the low-oxygen ambient 29 may be in a range from 10 Pa to 120 kPa. The atmospheric pressure in the standard atmospheric condition is 101.33 kPa. In one embodiment, the partial pressure of oxygen in the low-oxygen ambient 29 may be in a range from 1.0×10⁻⁶ Pa to 10.13 kPa. Generally, the low oxygen partial pressure in the low-oxygen ambient 29 may be provided by reducing the total pressure of the low-oxygen ambient 29 and/or by reducing the fraction of oxygen in the composition of the ambient gas in the low-oxygen ambient 29. In one embodiment, the molecular fraction of oxygen in the low-oxygen ambient 29 may be in a range from 1.0×10⁻⁹ to 0.2095 (which is the fraction of oxygen atoms in the normal atmospheric composition). A suitable mechanism (not expressly shown) such as an ambient gas supply nozzle, an exhaust port, and/or a vacuum pumping port may be provided as needed to maintain the composition and the pressure of the low-oxygen ambient 29 at a pre-determined level.

The chamber enclosure 31 may comprise a first opening and a second opening. A first door 32 may be provided at the first opening in a manner that provides sealing of a volume that is enclosed by the chamber enclosure 31. A second door 34 may be provided at the second opening in a manner that provides sealing of the volume that is enclosed by the chamber enclosure 31. Suitable door actuation mechanisms may be provided for the first door 32 and the second door 34 so that the first door 32 and the second door 34 may be opened and closed to provide transport of semiconductor packages and packaging substrates in and out of the chamber enclosure 31. While the present disclosure is described using an embodiment in which a first door 32 and a second door 34 are located on opposite sides of the low-oxygen ambient, embodiments are expressly contemplated herein in which the first door 32 and the second door 34 are arranged differently, or merged as a single door.

A thermocompressive bonding head 40 may be provided in the process chamber. The thermocompressive bonding head 40 may be configured to hold and carry a semiconductor package 10 over a stage 90, and to induce reflow of solder material portions 30 on the semiconductor package 10 so that the semiconductor package 10 (e.g., 101, 102, 103) is bonded to a respective packaging substrate 20 (e.g., 201, 202, 203). Generally, the thermocompressive bonding head 40 may include all necessary components that are configured to provide thermocompressive bonding between a semiconductor package 10 and a packaging substrate 20. Generally, a commercially available thermocompressive bonding head may be used.

At least one plasma treatment system 60 configured to generate a respective plasma jet may be located within the process chamber (31, 32, 34). The at least one plasma treatment system 60 may comprise only a single plasma treatment system 60, or may comprise a plurality of plasma treatment systems 60 (such as a first plasma treatment system 601, a second plasma treatment system 602, etc.). Each of the at least one plasma treatment system 60 comprises a respective plasma nozzle 61 configured to generate a respective atmospheric pressure plasma jet containing ions of a respective reducing gas, i.e., a respective gas that may combine with oxygen atoms to de-oxidize a surface. Each plasma nozzle 61 of the at least one plasma treatment system 60 may be configured such that each plasma jet is directed toward solder material portions on a semiconductor package 10 under a pre-bonding clean process. The plasma jet direction (i.e., the flow direction of a plasma jet as ejected from a respective plasma nozzle 61) of each plasma treatment system 60 may be tilted with respect to the vertical direction, and may, or may not, be tilted with respect to the horizontal direction. The tilt angle of each plasma jet direction relative to the horizontal direction may be generally in a range from −89 degrees to +89 degrees, such as from −45 degrees to +45 degrees, although lesser and greater tilt angles may also be used. Generally, the tilt angle θ may be a fixed angle, or may be a in-situ controllable variable angle.

A stage 90 configured to mount a plurality of packaging substrate 20 may be provided within the process chamber (31, 32, 34). In one embodiment, the plurality of packaging substrates 20 may be provided as portions of a wafer 20W, and the stage 90 may be configured to mount a wafer 20W thereupon.

The embodiment bonding apparatus 100 may include various transport systems to move the thermocompressive bonding head 40, the at least one plasma treatment system 60, a plurality of semiconductor packages 10, and a plurality of packaging substrates 20 (which may be provided within a wafer). For example, a first transport system 70 may be configured to transport the thermocompressive bonding head 40 and a selected semiconductor package 10 toward the stage 90, and specifically, to a bonding position selected from a plurality of package bonding positions located above the stage 90. The first transport system 70 may comprise a first horizontal transport system 70H and a first vertical transport system 70V. A second transport system 80 may be configured to transport the at least one plasma treatment system 60 to a respective selected plasma treatment position. The plasma treatment positions for each plasma treatment system 60 may be selected from a plurality of plasma treatment positions. The second transport system 80 may comprise a second horizontal transport system 80H and a second vertical transport system 80V. Each of the transport systems (70, 80) may comprise at least one rail and at least one motorized structure.

Generally, movement of any movable elements within the embodiment bonding apparatus 100 may be controlled by a process controller 300. Further, operation of all elements within an embodiment bonding apparatus 100 may be controlled by the process controller 300. For example, the process controller 300 may be configured to control operation of the at least one plasma treatment system 60 and the thermocompressive bonding head 40.

According to an aspect of the present disclosure, an embodiment bonding apparatus 100 may be configured to perform fluxless solder bonding. In this embodiment, the embodiment bonding apparatus 100 is free of any flux material within a volume of the process chamber (31, 32, 34), and does not include any conduit for flowing any flux material therein or thereupon. In other words, a flux material may not be present within, or on, the exemplary bonding apparatus 100.

To initiate a bonding process, the first door 32 may be opened. In one embodiment, the ambient outside the low-oxygen ambient 29 may be controlled to be similar to the low oxygen ambient so that disturbance to the composition and the pressure of the low-oxygen ambient 29 may be minimized. A plurality of semiconductor packages 10 may be loaded into the chamber enclosure 31. In the illustrated example, the plurality of semiconductor packages 10 may comprise a first semiconductor package 101, a second semiconductor package 102, and a third semiconductor package 103. While the present invention is described using an embodiment in which three semiconductor packages 10 (e.g., 101, 102, 103) may be loaded into the chamber enclosure 31, embodiments are expressly contemplated herein in which two or more than three semiconductor packages 10 may be loaded into the chamber enclosure 31 at a time. The total number of semiconductor packages 10 loaded into the chamber enclosure 31 may be in a range from 2 to 10¹³, although a greater number may also be used.

As used herein, a semiconductor package 10 refers to any of a semiconductor die that functions as a stand-alone package, or a composite package including an interposer and at least one semiconductor die. In one embodiment, one, a plurality, and/or each, of the semiconductor packages 10 loaded into the chamber enclosure 31 may comprise a respective fan-out package including at least one semiconductor chip and an interposer.

A plurality of packaging substrates 20 (e.g., 201, 202, 203) may be loaded into the chamber enclosure 31. In the illustrated example, the plurality of packaging substrates 20 may comprise a first packaging substrate 201, a second packaging substrate 202, and a third packaging substrate 203. While the present invention is described using an embodiment in which three packaging substrates 20 may be loaded into the chamber enclosure 31, embodiments are expressly contemplated herein in which two or more than three packaging substrates 20 may be loaded into the chamber enclosure 31 at a time. The total number of packaging substrates 20 loaded into the chamber enclosure 31 may be in a range from 2 to 10¹³, although a greater number may also be used. In one embodiment, the number of the packaging substrates 20 that are loaded into the chamber enclosure 31 may be the same as the number of semiconductor packages 10 that are loaded into the chamber enclosure 31.

In one embodiment, the plurality of packaging substrates 20 may be provided as portions of a wafer 20W. In one embodiment, the wafer 20W may comprise a two-dimensional array of packaging substrates 20. In the illustrated example, the wafer 20W comprises a first packaging substrate 201, a second packaging substrate 202, and a third packaging substrate 203 therein. The various packaging substrates 20 may be portions of the wafer 20W that are laterally spaced apart from one another.

In one embodiment, each of the semiconductor packages 10 may comprise package-side bonding structures 18 to which solder material portions 30 are attached. For example, the first semiconductor package 101 may comprise first package-side bonding structures 18 to which first solder material portions 30 are attached, the second semiconductor package 102 may comprise second package-side bonding structures 18 to which second solder material portions 30 are attached, and the third semiconductor package 103 may comprise third package-side bonding structures 18 to which third solder material portions 30 are attached.

In one embodiment, each of the packaging substrates 20 may comprise substrate-side bonding structures 28. For example, the first packaging substrate 201 may comprise first substrate-side bonding structures 28, the second packaging substrate 202 may comprise second substrate-side bonding structures 28, and the third packaging substrate 203 may comprise third substrate-side bonding structures 28.

Generally, the semiconductor packages 10 and the packaging substrates 20 may be loaded into the process chamber (31, 32, 34) while the first door 32 is open. While the present disclosure is described using an embodiment in which solder material portions 30 are attached to semiconductor packages 10, embodiments are expressly contemplated herein in which the solder material portions 30 are attached to the packaging substrates 20. As discussed above, no flux material is present on the solder material portions 30, the semiconductor packages 10, or the packaging substrates 20.

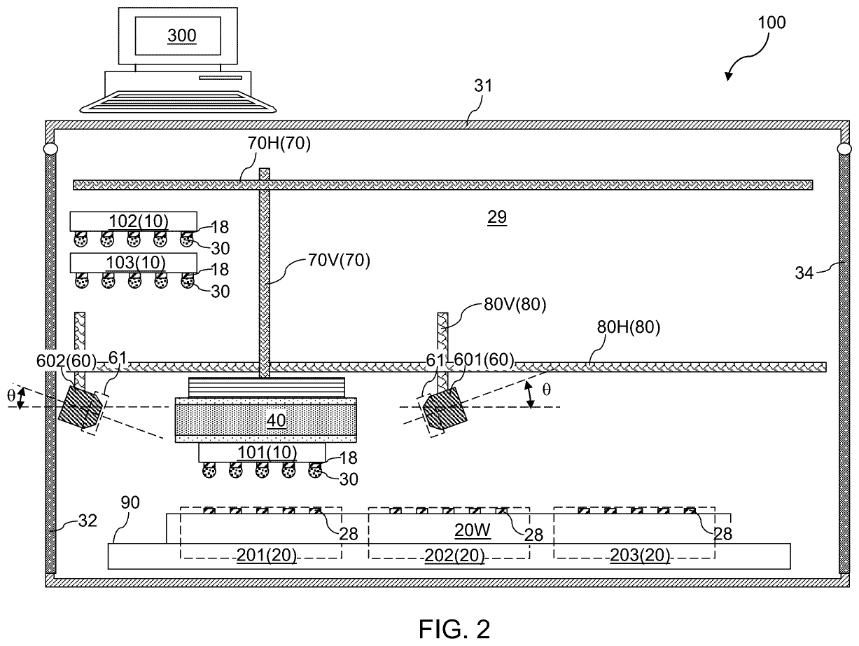

Referring to FIG. 2, the first door 32 may be closed after loading the semiconductor packages 10 and the packaging substrates 20 into the process chamber (31, 32, 34). The first transport system 70 may be used to transport the first semiconductor package 101 toward the first packaging substrate 201. In this embodiment, the first semiconductor package 101 may be mounted to a bottom side of the thermocompressive bonding head 40, and the combination of the thermocompressive bonding head 40 and the first semiconductor package 101 may be positioned above first substrate-side bonding structures 28 located on the first packaging substrate 201. The first semiconductor package 101 may be oriented such that the first solder material portions 30 of the first semiconductor package 101 face the first substrate-side bonding structures 28 located on the first packaging substrate 201.

The at least one plasma treatment system 60 may be transported to an initial first package clean position such that each plasma nozzle 61 of the at least one plasma treatment system 60 may be directed sideways toward the first solder material portions 30 bonded to the first semiconductor package 101. In embodiments in which the at least one plasma treatment system 60 comprises a plurality of plasma treatment systems 60, the plurality of plasma treatment systems 60 may be positioned around the first semiconductor package 101. In one embodiment, the plurality of plasma treatment systems 60 may be azimuthally spaced apart from one another around a vertical axis passing through a geometrical center of the thermocompressive bonding head 40.

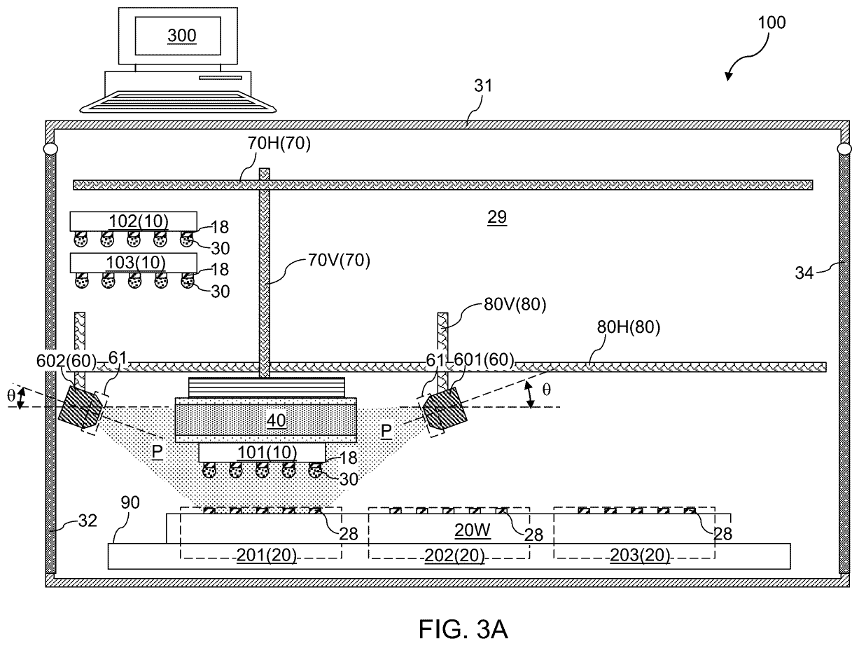

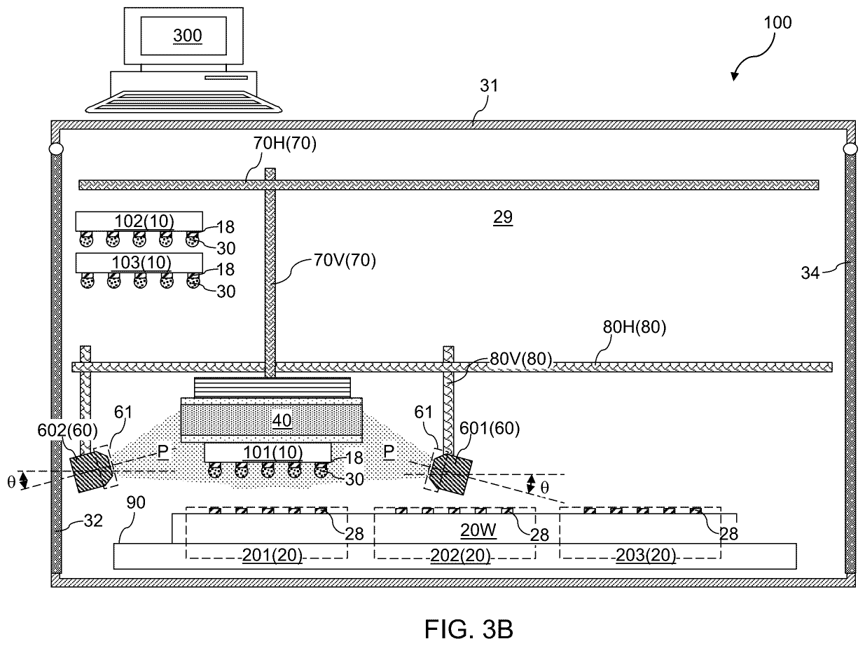

Referring to FIG. 3A, a first plasma package-treatment process may be performed. In one embodiment, the first plasma package-treatment process may comprise a first plasma treatment step that commences while the first semiconductor package 101 is mounted to the bottom side of the thermocompressive bonding head 40 and faces the first packaging substrate 201. The first plasma package-treatment process may be performed on the first semiconductor package 101 in the low-oxygen ambient 29 by generating at least one first plasma jet P from each of the at least one plasma treatment system 60 (e.g., 601, 602), and by directing the at least one first plasma jet P to the first solder material portions 30 bonded to the first semiconductor package 101.

In one embodiment, the at least one plasma treatment system 60 comprise a plurality of plasma treatment systems 60, and each of the at least one first plasma jet P may be directed to the first solder material portions 30 throughout the first plasma package-treatment process. In one embodiment, each plasma nozzle 61 of the at least one plasma treatment system 60 may be directed to the first solder material portions 30 along at least one respective non-vertical direction throughout the first plasma package-treatment process.

The at least one plasma treatment system 60 may be any type of plasma treatment system configured to clean surfaces of solder material portions or bonding structures on a semiconductor package. The plasma nozzle 61 of each plasma treatment system 60 may be a line-type plasma nozzle, a matrix-type plasma nozzle, a round plasma nozzle, a rectangular plasma nozzle, or a plasma nozzle having an irregular shape.

Each plasma nozzle 61 of a plasma treatment system 60 comprises at least one plasma outlet, which may be a plurality of plasma outlets. During the first plasma package-treatment process, the vertical distance between each plasma nozzle 61 of the at least one plasma treatment system 60 and the first solder material portions 30 on the first semiconductor package 101 may be in a range from 1 mm to 50 mm, although lesser and greater vertical distances may also be used. In one embodiment, the lateral distance between the outermost edge of the solder material portions 30 and a most proximal portion of each plasma nozzle 61 may be in a range from 1 mm to 200 mm, although lesser and greater lateral distances may also be used.

The at least one plasma treatment system 60 forms a reducing plasma (i.e., a de-oxidizing plasma) around the first solder material portions 18 by generating a plasma jet P, which is an atmospheric pressure plasma jet (APPJ). Generally, an atmospheric pressure plasma jet (APPJ) may be generated by passing a gas (such as air, argon, or helium) through a high voltage electrical discharge. The resulting plasma is composed of highly reactive species, such as ions and radicals, which may be used for a variety of industrial and research applications. In one embodiment of the present disclosure, the first APPJ and the second APPJ are used for surface cleaning. Specifically, ions in each plasma jet P are directed towards the first solder material portions 30 to clean the surfaces of the first solder material portions 30. The high energy species in the plasma interact with the surfaces, thereby breaking down, and removing, contaminants on the first solder material portions 30. In one embodiment, each plasma jet P uses ions of a reducing gas to reduce and/or remove contaminants (such as oxygen or water vapor) on the surfaces of the first solder material portions 30. A reducing gas is mixed with a respective plasma jet P, and the resulting reactive species are directed towards the surfaces to be cleaned, effectively reducing and removing the contaminants on the surfaces.

Embodiment reducing gases that may be used to for each plasma jet P from the at least one plasma treatment system 60 may include, but are not limited, to hydrogen, various hydride gases (such as methane, ammonia, acetylene, etc.), carbon monoxide, and various volatile compounds including hydrogen radicals. Hydrogen gas is a strong reducing agent and may be used to remove oxides, sulfates, and other contaminants from surfaces. Methane is a hydrocarbon gas that may be used to remove carbon-based by contaminants from surfaces. Ammonia is a weak reducing agent that may be used to remove nitrides and other nitrogen-based contaminants from surfaces. Carbon dioxide may be used to remove organic contaminants from surfaces. Nitrogen may be used to remove oxygen-based contaminants. Propane is a hydrocarbon gas that may be used to remove carbon-based contaminants from surfaces. In some other embodiments, non-reducing gases such as argon and helium may be optionally used to cool down the plasma, and/or to protect the plasma jet and to improve the plasma properties. Generally, any ion that acts as a reducing agent may be used. Each atmospheric pressure plasma jets generated by the at least one plasma treatment system 60 does not need to be at an “atmospheric” pressure, but may be any pressure that may be used to generate the condition of an atmospheric pressure plasma jet known in the art.

The temperature of the low-oxygen ambient 29 in the process chamber (31, 32, 34) is lower than the reflow temperature of the solder material portions 30. The temperature of the low-oxygen ambient 29 may be in range from 10 degrees Celsius to 450 degrees Celsius, and may be in a range from 10 degrees Celsius to 200 degrees Celsius, such as from 10 degrees Celsius to 100 degrees Celsius. Generally, the first plasma package-treatment process may be performed on the first semiconductor package 101 in the low-oxygen ambient 29 having an oxygen partial pressure that is lower than 17 kPa.

Generally, the process controller 300 comprises a processor and a memory in communication with the processor, and is loaded with a program that controls locations and angles of each component within the exemplary bonding apparatus 100.

Subsequently, the first semiconductor package 101 may be transported toward the first packaging substrate 201. For example, the combination of the thermocompressive bonding head 40 and the first semiconductor package 101 may be vertically moved toward the first packaging substrate 201 to reduce the vertical distance between the first semiconductor package 101 and the first packaging substrate 201 until the first semiconductor package 101 is positioned at a first bonding position at which thermocompressive bonding with the first packaging substrate 201 may be performed. The first transport system 70 may be used to transport the combination of the thermocompressive bonding head 40 and the first semiconductor package 101 to the first bonding position.

In one embodiment, the first semiconductor package 101 moves along a vertical direction toward the first semiconductor package 101 in a first plasma treatment step during the first plasma package-treatment process. In one embodiment, the at least one first plasma jet P is generated by at least one plasma treatment system 60 having a respective plasma nozzle 61, and the at least one plasma treatment system 60 moves along the vertical direction at a same speed as the first semiconductor package 101 during the first plasma treatment step.

In one embodiment, the second transport system 80 may be configured to transport the at least one plasma treatment system 60 at a same speed as the first semiconductor package 101 while the first semiconductor package 101 is transported toward the stage 90. Generally, the controller 300 may be loaded with an automated program to control synchronous movement of the at least one plasma treatment system 60 and the combination of the thermocompressive bonding head 40 and the first semiconductor package 101. The first plasma treatment step of the first plasma package-treatment process may be continued throughout the movement of the first semiconductor package 101. The first solder material portions 30 may be cleaned by the first plasma jet P during transport of the first semiconductor package 101 toward the first packaging substrate 201 loaded on the stage 90. In one embodiment, the tilt angle q of the nozzle direction of the at least one plasma treatment system 60 may remain constant during transport of the combination of the thermocompressive bonding head 40 and the first semiconductor package 101 to the first bonding position.

Referring to FIG. 3B, an alternative configuration of the exemplary bonding apparatus during a first plasma treatment step of a first plasma package-treatment process according to an embodiment of the present disclosure. The alternative configuration of the exemplary bonding apparatus 100 illustrated in FIG. 3B may be derived from the configuration of the exemplary bonding apparatus 100 illustrated in FIG. 3A by altering the position(s) of the at least one plasma treatment system 60 and the tilt angle q of the nozzle direction, i.e., the plasma jet direction, of the at least one plasma treatment system 60. For example, the at least one plasma treatment system 60 may remain stationary throughout the first plasma treatment step and/or throughout the first plasma package-treatment process such that the first plasma jet(s) P generated from the at least one plasma treatment system 60 may be continuously directed to the first solder material portions 30 on the first semiconductor package 101 throughout movement of the assembly of the thermocompressive bonding pad 40 and the first semiconductor package 101 toward the first semiconductor package 101. For example, the tilt angle θ of each plasma treatment system 60 may be continuously changed so that the first plasma jet(s) P from the at least one plasma treatment system is/are continuously directed to the first solder material portions 30 such that all physically exposed surfaces of the first solder material portions 30 are continuously cleaned during transport of the first semiconductor package 101 toward the first packaging substrate 201.

In one embodiment, the at least one first plasma jet P is generated by at least one plasma treatment system 60 having a respective plasma nozzle 61, and each plasma nozzle 61 of the at least one first plasma treatment system 60 changes a respective nozzle direction such that the at least one first plasma jet P is directed at the first solder material portions 30 during a vertical movement of the first semiconductor package 101 toward the stage 90. After the first semiconductor package 101 reaches the first bonding position at which thermocompressive bonding with the first packaging substrate 201 may be performed, each first plasma jet P may be directed toward first substrate-side bonding structures 28 which are located on a surface of the first packaging substrate 20.

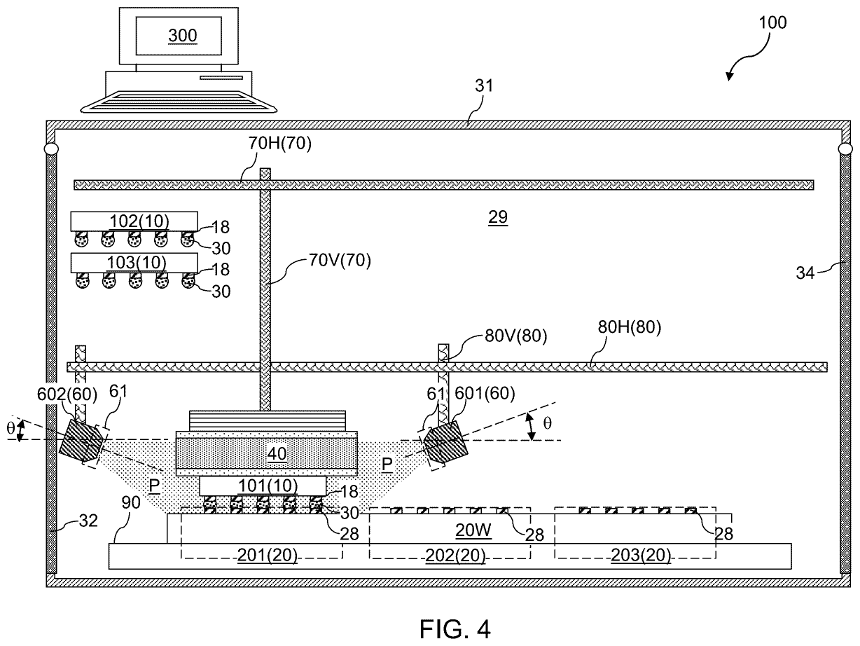

Referring to FIG. 4, upon arrival of the first semiconductor package 101 to the first bonding position, a second plasma treatment step of the first plasma package-treatment process may be commence. The second plasma treatment step is a continuation of the first plasma treatment step that commences when the first semiconductor package 101 is positioned at the first bonding position. Each first plasma jet P may be directed toward first substrate-side bonding structures 28 when the first semiconductor package 101 is located at the first bonding position.

Generally, the first solder material portions 30 may be brought onto, or in proximity to, the first substrate-side bonding structures 28 while the at least one first plasma jet P is directed to the first solder material portions 30. The first substrate-side bonding structures are treated with the first plasma jet P prior to bonding the first semiconductor package 101 to the first packaging substrate 201.

In one embodiment, the first semiconductor package 101 remains stationary after the first semiconductor package 101 is brought onto, or in proximity to, the first substrate-side bonding structures 28 during the second plasma treatment step of the first plasma package-treatment process. According to an aspect of the present disclosure, the first solder material portions 30 and the first substrate-side bonding structures 28 may be simultaneously treated with the at least one first plasma jet P.

Subsequently, a first bonding process may be performed to bond the first solder material portions 30 of the first semiconductor package 101 to the first substrate-side bonding structures 28 (which may be bonding pads such as controlled collapse chip connection bonding pads). The bonding processes used in the present disclosure may be fluxless bonding processes. In this embodiment, the first solder material portions 30 and the first substrate-side bonding structures 28 are not in contact with any flux material prior to, and during, the first plasma package-treatment process that bonds the first semiconductor package 101 to the first packaging substrate 201.

Generally, the first semiconductor package 101 may be bonded to the first packaging substrate 201 while, or after, the first substrate-side bonding structures 28 are treated with the first plasma jet P. In one embodiment, the first semiconductor package 101 may be bonded to the first packaging substrate 201 while the first substrate-side bonding structures 28 are treated with the first plasma jet P. In this embodiment, the first bonding process may occur simultaneously with the second plasma treatment step of the first plasma package-treatment process. In another embodiment, the first semiconductor package 101 may be bonded to the first packaging substrate 201 after the first substrate-side bonding structures 28 are treated with the first plasma jet P. In this embodiment, the first bonding process may occur after termination of the first plasma package-treatment process. A first bonded assembly of the first semiconductor package 101 and the first packaging substrate 201 may be formed by the first bonding process.

In embodiments in which the first bonding process may occur simultaneously with the second plasma treatment step of the first plasma package-treatment process, the first plasma jet P may be active during the thermocompressive bonding process. Generally, the volume in which the first plasma jet P is active may include the entire space between the first semiconductor package 101 and the first packaging substrate 201. This volume may have a lateral extent that is greater than the area of the first semiconductor package 101 and the area of the first packaging substrate 201. In embodiments in which the at least one plasma treatment system 60 comprises a plurality of plasma treatment systems 60, the plurality of plasma treatment systems 60 may laterally surround the thermocompressive bonding head 40. The range of each first plasma jet P is greater than one half of the lateral extent of the first semiconductor package 101, and the array of first solder material portions 30 may be laterally surrounded by the at least one first plasma jet P during, and prior to, the thermocompressive bonding process. In embodiments in which a single plasma treatment system 60 is used, the range of the first plasma jet P is greater than the lateral extent of the array of first solder material portions 30 so that each of the first solder material portions 30 is exposed to the first plasma jet P. The thermocompressive bonding process may form a bonded assembly including the first semiconductor package 101 and the first packaging substrate 201 such that the joint interfaces do not have any bonding line interfaces.

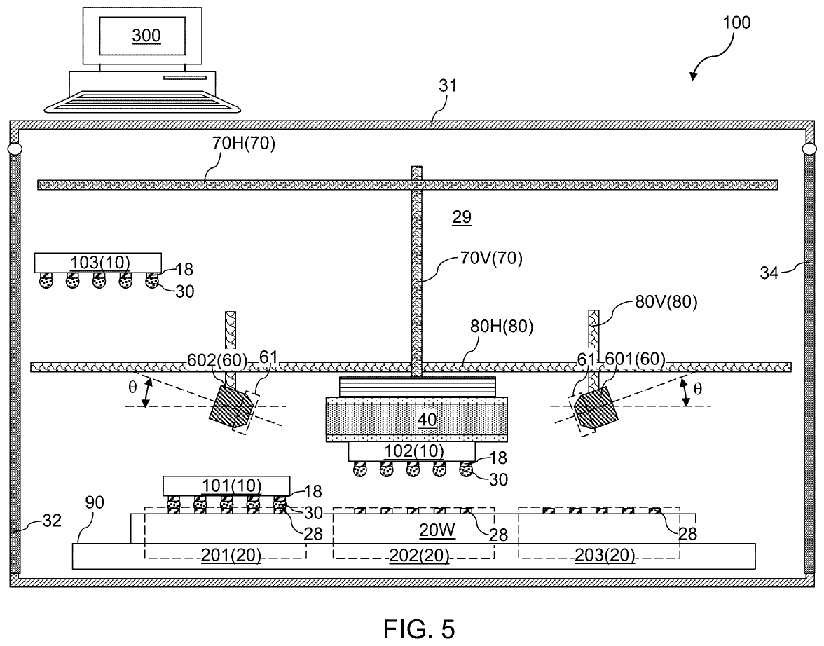

Referring to FIG. 5, the first transport system 70 may be used to transport the second semiconductor package 102 toward the second packaging substrate 201. In this embodiment, the second semiconductor package 102 may be mounted to the bottom side of the thermocompressive bonding head 40, and the combination of the thermocompressive bonding head 40 and the second semiconductor package 102 may be positioned above second substrate-side bonding structures 28 located on the second packaging substrate 201. The second semiconductor package 102 may be oriented such that the second solder material portions 30 of the second semiconductor package 102 face the second substrate-side bonding structures 28 located on the second packaging substrate 201.

The at least one plasma treatment system 60 may be transported to an initial second package clean position such that each plasma nozzle 61 of the at least one plasma treatment system 60 is directed sideways toward the second solder material portions 30 bonded to the second semiconductor package 102. In embodiments in which the at least one plasma treatment system 60 comprises a plurality of plasma treatment systems 60, the plurality of plasma treatment systems 60 may be positioned around the second semiconductor package 102. In one embodiment, the plurality of plasma treatment systems 60 may be azimuthally spaced apart from one another around a vertical axis passing through a geometrical center of the thermocompressive bonding head 40. In one embodiment, one of the plurality of plasma treatment systems 60 may overlie, and have an real overlap in a plan view with, the bonded assembly of the first semiconductor package 101 and the first packaging substrate 201.

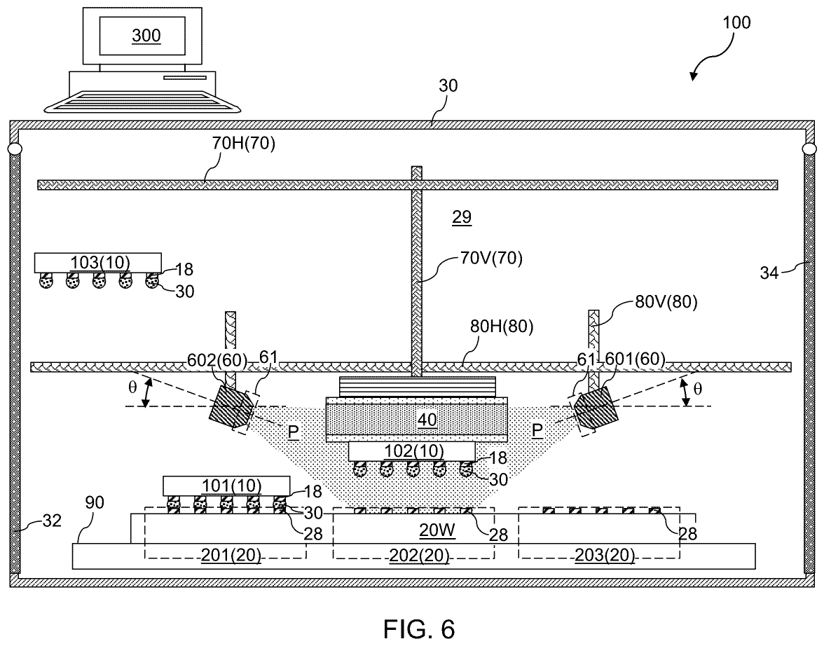

Referring to FIG. 6, the processing steps described with reference to FIG. 3A or FIG. 3B may be performed with a necessary change in the location of the at least one plasma treatment system 60 to perform a first plasma treatment step of a second plasma package-treatment process. Generally, the second plasma package-treatment process may be performed on the second semiconductor package 102 in the low-oxygen ambient 29 by directing at least one second plasma jet P to second solder material portions 30 bonded to the second semiconductor package 102. The at least one plasma treatment system 60 may move as described with reference to FIG. 3A, and/or the tilt angle θ of each plasma nozzle 61 of the at least one plasma treatment system 60 may change as described with reference to FIG. 3B, during the first plasma treatment step of the second plasma package-treatment process.

Generally, each of the at least one second plasma jet P that is generated by the at least one plasma treatment system 60 (which may be a plurality of plasma treatment systems 60) has a respective plasma nozzle 61 that is directed to the second solder material portions throughout the second plasma package-treatment process. In embodiments in which a plurality of plasma treatment system 60 is used, one of the plurality of plasma treatment systems 60 may be disposed over an assembly of the first semiconductor package 101 and the first packaging substrate 201 during the second plasma package-treatment process on the second semiconductor package 102 with an areal overlap with the first packaging substrate 201 along a vertical direction.

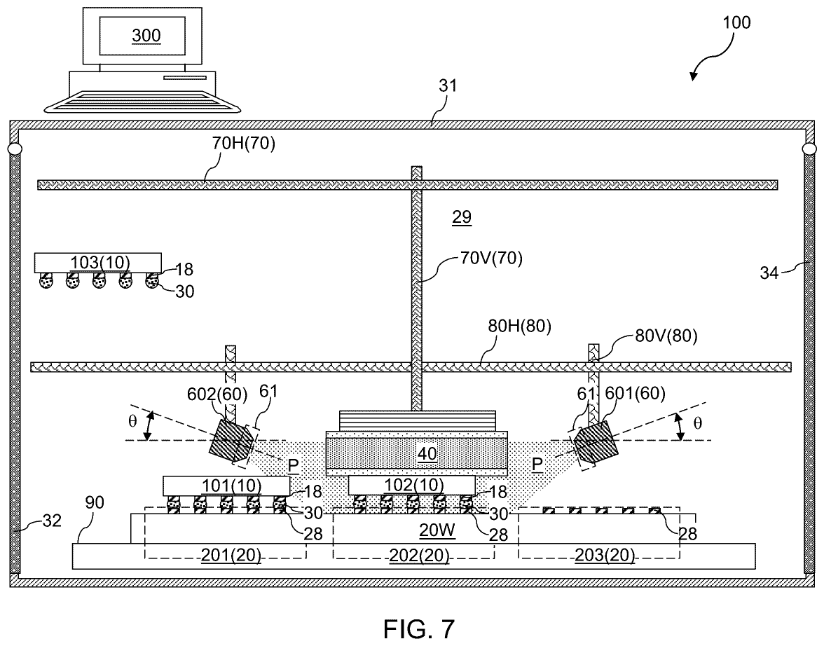

Referring to FIG. 7, the assembly of the thermocompressive bonding head 40 and the second semiconductor package 102 may be transported to a second bonding position for bonding with the second packaging substrate 202. The second solder material portions 30 may be transported onto, or in proximity to, second substrate-side bonding structures 28 located on the second packaging substrate 202 while the at least one second plasma jet P is directed to the second solder material portions 30. Subsequently, the second substrate-side bonding structures are treated with the second plasma jet P during a second plasma treatment step of the second plasma package-treatment process. Generally, the processing steps described with respect to FIG. 4 may be performed with a necessary change in the location of the at least one plasma treatment system 60 to perform a second plasma treatment step of the second plasma package-treatment process and the second bonding process.

The second semiconductor package 102 may be bonded to the second packaging substrate 202 while, or after, the second substrate-side bonding structures 28 are treated with the second plasma jet P. In one embodiment, the second semiconductor package 102 may be bonded to the second packaging substrate 202 while the second substrate-side bonding structures 28 are treated with the second plasma jet P. In this embodiment, the second bonding process may occur simultaneously with the second plasma treatment step of the second plasma package-treatment process. In another embodiment, the second semiconductor package 102 may be bonded to the second packaging substrate 202 after the second substrate-side bonding structures 28 are treated with the second plasma jet P. In this embodiment, the second bonding process may occur after termination of the second plasma package-treatment process. A second bonded assembly of the second semiconductor package 102 and the second packaging substrate 202 may be formed by the second bonding process.

In embodiments in which the second bonding process may occur simultaneously with the second plasma treatment step of the second plasma package-treatment process, the second plasma jet P may be active during the thermocompressive bonding process. Generally, the volume in which the second plasma jet P is active may include the entire space between the second semiconductor package 102 and the second packaging substrate 202. This volume may have a lateral extent that is greater than the area of the second semiconductor package 102 and the area of the second packaging substrate 202. In embodiments in which the at least one plasma treatment system 60 comprises a plurality of plasma treatment systems 60, the plurality of plasma treatment systems 60 may laterally surround the thermocompressive bonding head 40. The range of each second plasma jet P is greater than one half of the lateral extent of the second semiconductor package 102, and the array of second solder material portions 30 may be laterally surrounded by the at least one second plasma jet P during, and prior to, the thermocompressive bonding process. In embodiments in which a single plasma treatment system 60 is used, the range of the second plasma jet P is greater than the lateral extent of the array of second solder material portions 30 so that each of the second solder material portions 30 is exposed to the second plasma jet P. The thermocompressive bonding process may form a bonded assembly including the second semiconductor package 102 and the second packaging substrate 202 such that the joint interfaces do not have any bonding line interfaces.

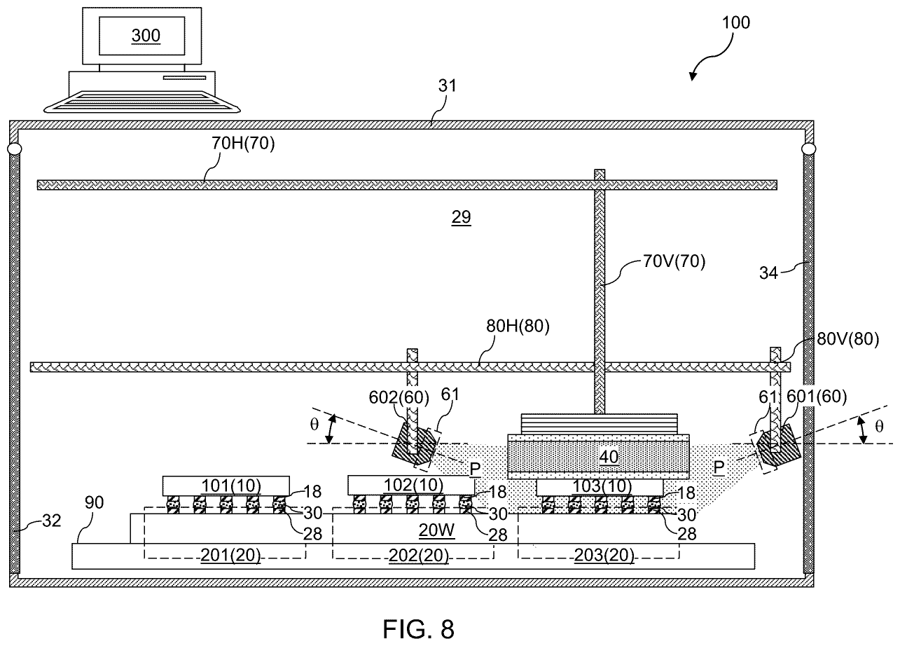

Referring to FIG. 8, the processing steps described with reference to FIGS. 5-7 may be performed mutatis mutandis using the third semiconductor package 103 and the third packaging substrate 203 to form a third bonded assembly of the third semiconductor package 103 and the third packaging substrate 203.

While the present disclosure is described using an embodiment in which the wafer 20W comprises three packaging substrates 20 and three semiconductor packages 10 are used to form three bonded assemblies of a respective semiconductor package 10 and a respective packaging substrate 20, embodiments are expressly contemplated herein in which a single bonded assembly, two bonded assemblies, or four or more bonded assemblies are formed. In embodiments in which three or more packaging substrates 20 are provided within the wafer 20, the three or more packaging substrates 20 may be arranged as a single linear array, or may be arranged as a two-dimensional array including a plurality of rows and columns that may, or may not, be orthogonal to one another. In one embodiment, each packaging substrate 20 in the wafer 20W may be bonded to a respective one of the semiconductor packages 10 that are loaded into the process chamber (31, 32, 34).

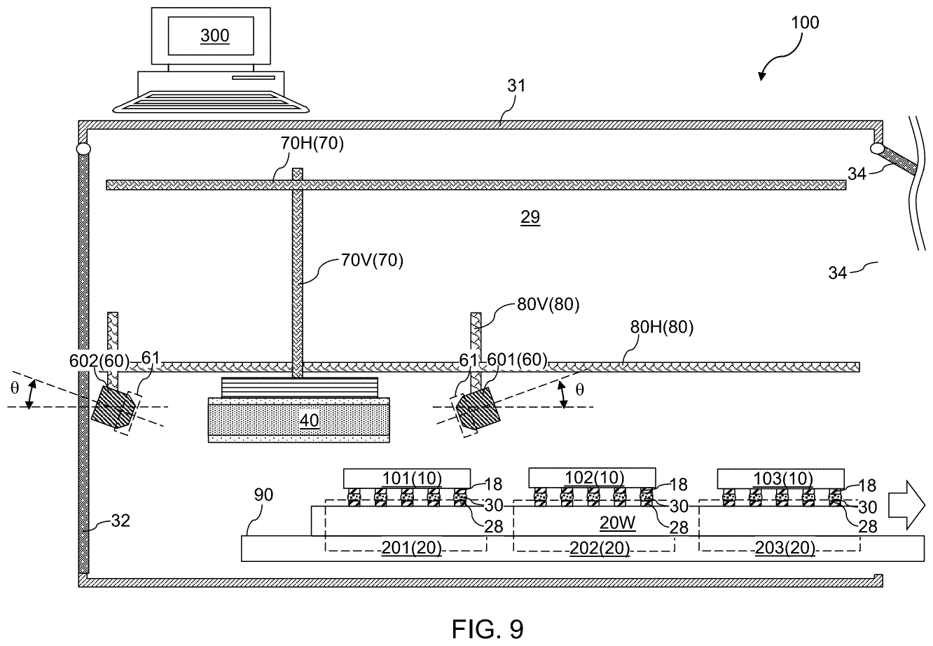

Referring to FIG. 9, the second door 34 of the process chamber (31, 32, 34) may be opened, and the bonded assemblies of a respective pair of a semiconductor package 10 and a packaging substrate 20 may be unloaded from the process chamber (31, 32, 34). In embodiments in which the packaging substrates 20 are provided as portions of a wafer 20W, an assembly of the wafer 20W and a two-dimensional array of semiconductor packages 10 may be unloaded.

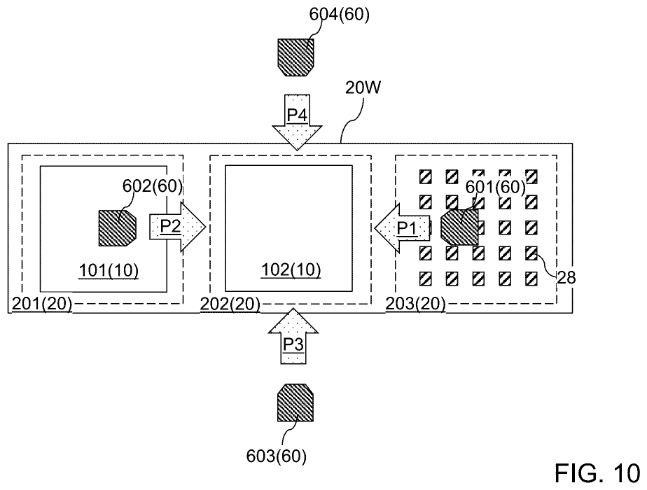

Referring to FIG. 10, a schematic top-down view of an inside of a first configuration of the exemplary bonding apparatus 100 is illustrated at a processing step of FIG. 6 according to an embodiment of the present disclosure. In the illustrated example, a plurality of plasma treatment systems 60 is used to generate multiple plasma jets. For example, a first plasma treatment system 601 may generate a first plasma jet P1, a second plasma treatment system 602 may generate a second plasma jet P2, a third plasma treatment system 603 may generate a third plasma jet P3, and a fourth plasma treatment system 604 may generate a fourth plasma jet P4. Each plasma treatment system 60 may have a respective plasma nozzle 61 that is directed to an array of solder material portions (not shown in FIG. 10) of a semiconductor package 10 under clean (which is the second semiconductor package 102 in the illustrated example). In one embodiment, one or more of the plurality of plasma treatment systems 60 may be disposed over a previously-formed bonded assembly of a semiconductor package 10 and a packaging substrate 20 (such as an assembly of the first semiconductor package 101 and the first packaging substrate 201) during the plasma package-treatment process on the semiconductor package 10 under clean (such as the second plasma package-treatment process on the second semiconductor package 102) with a respective areal overlap with the packaging substrate of the previously-formed bonded assembly (such as the first packaging substrate 201) along a vertical direction. In the illustrated example, the second plasma treatment system 601 may be positioned within the area of the first semiconductor die 101.

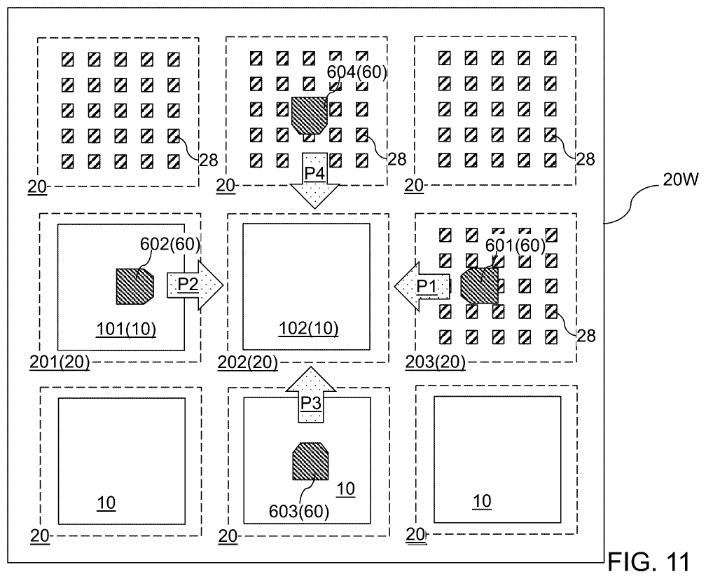

Referring to FIG. 11, a schematic top-down view of an inside of a second configuration of the exemplary bonding apparatus 100 is illustrated at a processing step of FIG. 6 according to an embodiment of the present disclosure. In this example, the wafer 20W may comprise a two-dimensional array of packaging substrates 20. A first subset of the packaging substrates 20 may be previously bonded to a respective semiconductor package 10, a second subset of the packaging substrates 20 may not yet be bonded to a respective semiconductor package 10, and one of the packaging substrates 20 may be under clean in preparation for bonding with a semiconductor package 10 (such as a second semiconductor package 102). In one embodiment, one or more of the plurality of plasma treatment systems 60 may be disposed over a previously-formed bonded assembly of a semiconductor package 10 and a packaging substrate 20 (such as an assembly of the first semiconductor package 101 and the first packaging substrate 201) during the plasma package-treatment process on the semiconductor package 10 under clean (such as the second plasma package-treatment process on the second semiconductor package 102) with a respective areal overlap with the packaging substrate of the previously-formed bonded assembly (such as the first packaging substrate 201) along a vertical direction. In the illustrated example, the second plasma treatment system 601 may be positioned within the area of the first semiconductor die 101, and the third plasma treatment system 603 may be positioned within the area of another semiconductor die 10.

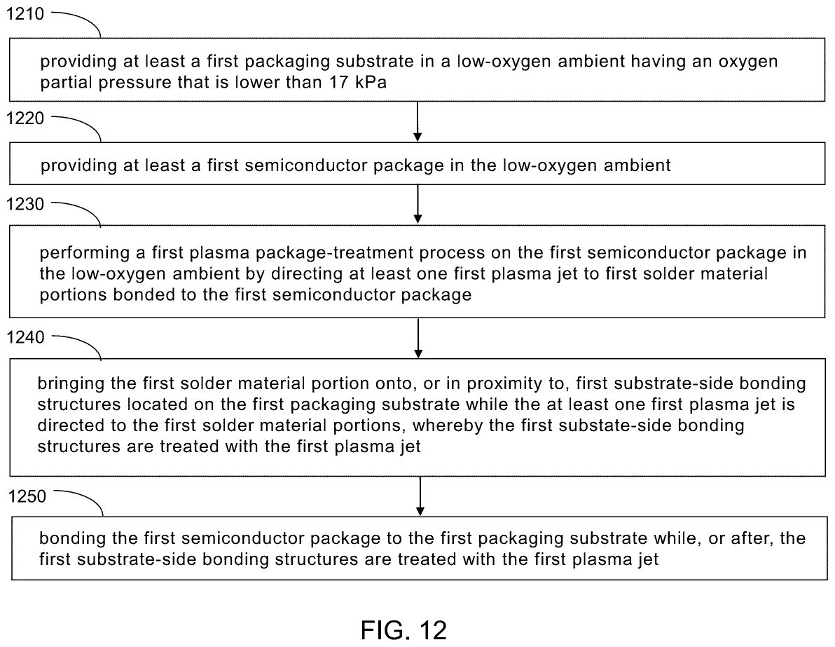

Referring to FIG. 12, a first flowchart illustrates steps for forming a bonded assembly according to an embodiment of the present disclosure.

Referring to step 1210 and FIG. 1, at least a first packaging substrate 20 may be provided in a low-oxygen ambient 29 having an oxygen partial pressure that is lower than 17 kPa.

Referring to step 1220 and FIG. 1, at least a first semiconductor package 101 may be provided in the low-oxygen ambient 29.

Referring to step 1230 and FIGS. 2, 3A, and 3B, a first plasma package-treatment process may be performed on the first semiconductor package 101 in the low-oxygen ambient 29 by directing at least one first plasma jet P to first solder material portions 30 bonded to the first semiconductor package 101.

Referring to steps 1240 and FIGS. 3A, 3B, and 4, the first solder material portions 30 may be brought onto, or in proximity to, first substrate-side bonding structures 28 located on the first packaging substrate 20 while the at least one first plasma jet P is directed to the first solder material portions 30, whereby the first substrate-side bonding structures are treated with the first plasma jet P.

Referring to step 1250 and FIGS. 5-11, the first semiconductor package 101 may be bonded to the first packaging substrate 20 while, or after, the first substrate-side bonding structures 28 are treated with the first plasma jet P.

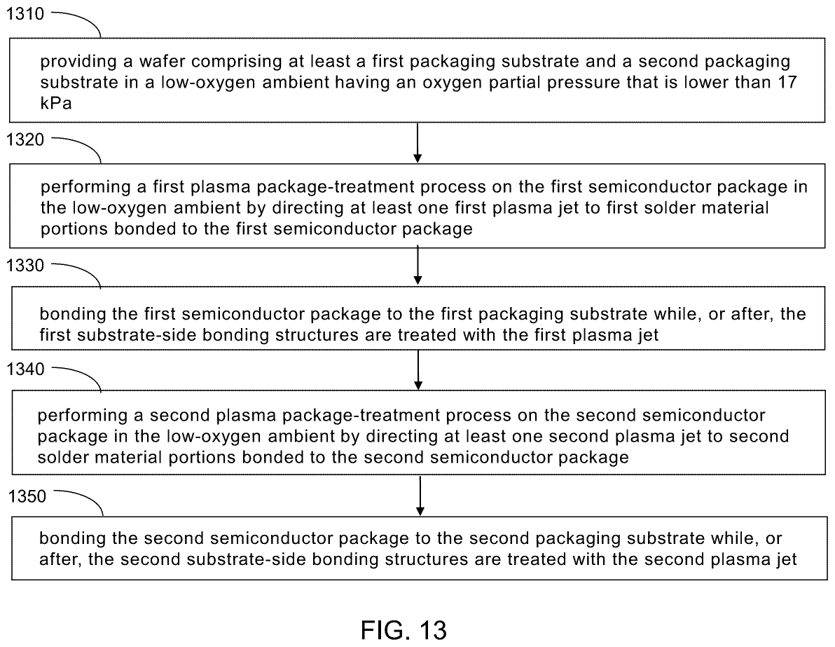

Referring to FIG. 13, a second flowchart illustrates steps for forming a bonded assembly according to an embodiment of the present disclosure.

Referring to step 1310 and FIG. 1, a wafer comprising at least a first packaging substrate 20 and a second packaging substrate 20 may be provided in a low-oxygen ambient 29 having an oxygen partial pressure that is lower than 17 kPa.

Referring to step 1320 and FIGS. 2, 3A, and 3B, a first plasma package-treatment process may be performed on the first semiconductor package 101 in the low-oxygen ambient 29 by directing at least one first plasma jet P to first solder material portions 30 bonded to the first semiconductor package 101.

Referring to step 1330 and FIG. 4, the first semiconductor package 101 may be bonded to the first packaging substrate 20 while, or after, the first substrate-side bonding structures 28 are treated with the first plasma jet P.

Referring to step 1340 and FIGS. 5 and 6, a second plasma package-treatment process may be performed on the second semiconductor package 10 in the low-oxygen ambient 29 by directing at least one second plasma jet P to second solder material portions 30 bonded to the second semiconductor package 10.

Referring to step 1350 and FIGS. 7-11, the second semiconductor package 10 may be bonded to the second packaging substrate 20 while, or after, the second substrate-side bonding structures 28 are treated with the second plasma jet P.

Referring to all drawings and according to various embodiments of the present disclosure, a method of forming a bonded assembly may be provided. The method may include the steps of: providing at least a first packaging substrate 20 in a low-oxygen ambient 29 having an oxygen partial pressure that is lower than 17 kPa; providing at least a first semiconductor package 10 in the low-oxygen ambient 29; performing a first plasma package-treatment process on the first semiconductor package 10 in the low-oxygen ambient 29 by directing at least one first plasma jet P to first solder material portions 30 bonded to the first semiconductor package 10; bringing the first solder material portions 30 onto, or in proximity to, first substrate-side bonding structures 28 located on the first packaging substrate 20 while the at least one first plasma jet P is directed to the first solder material portions 30, whereby the first substrate-side bonding structures 28 are treated with the first plasma jet P; and bonding the first semiconductor package 10 to the first packaging substrate 20 while, or after, the first substrate-side bonding structures 28 are treated with the first plasma jet P.

In one embodiment, the at least one first plasma jet P may be generated by at least one plasma treatment system 60 having a respective plasma nozzle 61 that is directed to the first solder material portions 30. In one embodiment, each plasma nozzle 61 of the at least one plasma treatment system 60 may be directed to the first solder material portions 30 along at least one respective non-vertical direction throughout the first plasma package-treatment process. In one embodiment, the first semiconductor package 10 moves along a vertical direction toward the first packaging substrate package 20 in a first plasma treatment step during the first plasma package-treatment process. In one embodiment, the at least one first plasma jet P may be generated by at least one plasma treatment system 60 having a respective plasma nozzle 61; and the at least one plasma treatment system 60 moves along the vertical direction at a same speed as the first semiconductor package 10 during the first plasma treatment step. In one embodiment, the first semiconductor package 10 may remain stationary after the first semiconductor package 10 is brought onto, or in proximity to, the first substrate-side bonding structures 28; and the first plasma package-treatment process comprises a second plasma treatment step during which the first solder material portions 30 and the first substrate-side bonding structures 28 may be simultaneously treated with the at least one first plasma jet P. In one embodiment, the at least one first plasma jet P may be generated by at least one plasma treatment system 60 having a respective plasma nozzle 61; and each plasma nozzle 61 of the at least one first plasma treatment system 60 changes a respective nozzle direction such that the at least one first plasma jet P may be directed at the first solder material portions 30 during a vertical movement of the first semiconductor package 10. In one embodiment, the first solder material portions 30 are not in contact with any flux material prior to, and during, the first plasma package-treatment process. In one embodiment, the first solder material portions 30 and the first substrate-side bonding structures 28 are not in contact with any flux material during bonding of the first semiconductor package to the first packaging substrate. In one embodiment, the method may further include: providing a second packaging substrate 202 in the low-oxygen ambient 29; providing a second semiconductor package 102 in the low-oxygen ambient 29; performing a second plasma package-treatment process on the second semiconductor package 102 in the low-oxygen ambient 29 by directing at least one second plasma jet P to second solder material portions 30 bonded to the second semiconductor package 102; bringing the second solder material portions 30 onto, or in proximity to, second substrate-side bonding structures 28 located on the second packaging substrate 202 while the at least one second plasma jet P may be directed to the second solder material portions 30, whereby the second substrate-side bonding structures 28 are treated with the second plasma jet P; and bonding the second semiconductor package 102 to the second packaging substrate 202 while, or after, the second substrate-side bonding structures 28 are treated with the second plasma jet P. In one embodiment, first packaging substrate 201 and the second packaging substrate 202 are provided within a same wafer 20W and are laterally spaced apart from each other.

Another embodiment is drawn to a method of forming a bonded assembly, the method may include the steps of: providing a wafer 20W comprising at least a first packaging substrate 201 and a second packaging substrate 202 in a low-oxygen ambient 29 having an oxygen partial pressure that is lower than 17 kPa; performing a first plasma package-treatment process on a first semiconductor package 101 in the low-oxygen ambient 29 by directing at least one first plasma jet P to first solder material portions 30 bonded to the first semiconductor package 101; bonding the first semiconductor package 101 to the first packaging substrate 201 while, or after, the first substrate-side bonding structures 28 are treated with the first plasma jet P; performing a second plasma package-treatment process on a second semiconductor package 102 in the low-oxygen ambient 29 by directing at least one second plasma jet P to second solder material portions 30 bonded to the second semiconductor package 102; and bonding the second semiconductor package 102 to the second packaging substrate 202 while, or after, the second substrate-side bonding structures 28 are treated with the second plasma jet P.

In one embodiment, the method may include bringing the first solder material portions 30 onto, or in proximity to, the first substrate-side bonding structures 28 while the at least one first plasma jet P may be directed to the first solder material portions 30, whereby the first substrate-side bonding structures 28 are treated with the first plasma jet P at least prior to bonding the first semiconductor package 101 to the first packaging substrate 201. In one embodiment, the method may include bringing the second solder material portions 30 onto, or in proximity to, the second substrate-side bonding structures 28 while the at least one second plasma jet P is directed to the second solder material portions 30, whereby the second substrate-side bonding structures 28 are treated with the second plasma jet P at least prior to bonding the second semiconductor package 102 to the second packaging substrate 202. In one embodiment, each of the at least one first plasma jet P and the at least one second plasma jet P is generated by a plurality of plasma treatment systems 60 having a respective plasma nozzle 61 that is directed to the first solder material portions 30 or to the second solder material portions 30 during operation; and one of the plurality of plasma treatment systems 60 is disposed over an assembly of the first semiconductor package 101 and the first packaging substrate 201 during the second plasma package-treatment process on the second semiconductor package 102 with an areal overlap with the first packaging substrate 201 along a vertical direction.

In another embodiment, an apparatus for forming a bonded assembly is provided. The apparatus comprises: a process chamber (31, 32, 34) including chamber enclosure 31 and an ambient control system configured to provide a low-oxygen ambient 29 having an oxygen partial pressure that is lower than 17 kPa; a stage 90 located in the process chamber (31, 32, 34) and configured to hold at least one packaging substrate 20 thereupon; a thermocompressive bonding head 40 located in the process chamber (31, 32, 34) and configured to hold and carry a semiconductor package 10 over a stage 90, and to induce reflow of solder material portions 30 on the semiconductor package 10; at least one plasma treatment system 60 located within the process chamber (31, 32, 34) and configured to generate a respective plasma jet P along a respective direction toward the solder material portions 30; a first transport system 70 configured to transport the thermocompressive bonding head 40 and the semiconductor package 10 toward the stage 90; and a process controller 300 configured to operate the at least one plasma treatment system 60 such that the respective plasma jet P is generated while the semiconductor package 10 is transported toward the stage 90.

In one embodiment, a second transport system 80 may be configured to transport the at least one plasma treatment system 60 at a same speed as the semiconductor package 10 while the semiconductor package 10 is transported toward the stage 90. In one embodiment, at least one plasma treatment system 60 comprises a respective plasma nozzle 61; and each plasma nozzle 61 of the at least one first plasma treatment system 60 changes a respective nozzle direction such that the respective plasma jet P is directed at the solder material portions 30 while the semiconductor package 10 is transported toward the stage 90. In one embodiment, the process controller 300 configured to operate the at least one plasma treatment system 60 such that the respective plasma jet P is directed toward a surface of one of the at least one packaging substrate 20 on the stage 90 after the semiconductor package 10 is transported to a bonding position overlying the one of the at least one packaging substrate 20. In one embodiment, the apparatus is free of any flux material within a volume of the process chamber (31, 32, 34), and does not include any conduit for flowing any flux material therein or thereupon.

The various embodiments of the present disclosure may be used to provide fluxless bonding of at least two pairs of semiconductor packages 10 and packaging substrates 20. Each pair of a semiconductor package 10 and a packaging substrate 20 may be cleaned using plasma treatment processes in a same low-oxygen ambient 29 without using any flux. Problems associated with use of flux during bonding may be avoided through use of the methods and the apparatus of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a bonded assembly, the method comprising:
providing at least a first packaging substrate in a low-oxygen ambient having an oxygen partial pressure that is lower than 17 kPa;
providing at least a first semiconductor package in the low-oxygen ambient;
performing a first plasma package-treatment process on the first semiconductor package in the low-oxygen ambient by directing at least one first plasma jet to first solder material portions bonded to the first semiconductor package;
bringing the first solder material portions onto, or in proximity to, first substrate-side bonding structures located on the first packaging substrate while the at least one first plasma jet is directed to the first solder material portions, whereby the first substrate-side bonding structures are treated with the first plasma jet; and
bonding the first semiconductor package to the first packaging substrate while, or after, the first substrate-side bonding structures are treated with the first plasma jet.

2. The method of claim 1, wherein the at least one first plasma jet is generated by at least one plasma treatment system having a respective plasma nozzle that is directed to the first solder material portions.

3. The method of claim 2, wherein each plasma nozzle of the at least one plasma treatment system is directed to the first solder material portions along at least one respective non-vertical direction throughout the first plasma package-treatment process.

4. The method of claim 1, wherein the first semiconductor package moves along a vertical direction toward the first packaging substrate package in a first plasma treatment step during the first plasma package-treatment process.

5. The method of claim 4, wherein:
the at least one first plasma jet is generated by at least one plasma treatment system having a respective plasma nozzle; and
the at least one plasma treatment system moves along the vertical direction at a same speed as the first semiconductor package during the first plasma treatment step.

6. The method of claim 4, wherein:
the first semiconductor package remains stationary after the first semiconductor package is brought onto, or in proximity to, the first substrate-side bonding structures; and
the first plasma package-treatment process comprises a second plasma treatment step during which the first solder material portions and the first substrate-side bonding structures are simultaneously treated with the at least one first plasma jet.

7. The method of claim 4, wherein:
the at least one first plasma jet is generated by at least one plasma treatment system having a respective plasma nozzle; and
each plasma nozzle of the at least one first plasma treatment system changes a respective nozzle direction such that the at least one first plasma jet is directed at the first solder material portions during a vertical movement of the first semiconductor package.

8. The method of claim 1, wherein the first solder material portions are not in contact with any flux material prior to, and during, the first plasma package-treatment process.

9. The method of claim 1, wherein the first solder material portions and the first substrate-side bonding structures are not in contact with any flux material during bonding of the first semiconductor package to the first packaging substrate.

10. The method of claim 1, further comprising:
providing a second packaging substrate in the low-oxygen ambient;
providing a second semiconductor package in the low-oxygen ambient;
performing a second plasma package-treatment process on the second semiconductor package in the low-oxygen ambient by directing at least one second plasma jet to second solder material portions bonded to the second semiconductor package;
bringing the second solder material portions onto, or in proximity to, second substrate-side bonding structures located on the second packaging substrate while the at least one second plasma jet is directed to the second solder material portions, whereby the second substrate-side bonding structures are treated with the second plasma jet; and
bonding the second semiconductor package to the second packaging substrate while, or after, the second substrate-side bonding structures are treated with the second plasma jet.

11. The method of claim 10, wherein first packaging substrate and the second packaging substrate are provided within a same wafer and are laterally spaced apart from each other.

12. A method of forming a bonded assembly, the method comprising:
providing a wafer comprising at least a first packaging substrate and a second packaging substrate in a low-oxygen ambient having an oxygen partial pressure that is lower than 17 kPa;
performing a first plasma package-treatment process on a first semiconductor package in the low-oxygen ambient by directing at least one first plasma jet to first solder material portions bonded to the first semiconductor package;
bonding the first semiconductor package to the first packaging substrate while, or after, the first substrate-side bonding structures are treated with the first plasma jet;
performing a second plasma package-treatment process on a second semiconductor package in the low-oxygen ambient by directing at least one second plasma jet to second solder material portions bonded to the second semiconductor package; and
bonding the second semiconductor package to the second packaging substrate while, or after, the second substrate-side bonding structures are treated with the second plasma jet.

13. The method of claim 12, further comprising bringing the first solder material portions onto, or in proximity to, the first substrate-side bonding structures while the at least one first plasma jet is directed to the first solder material portions, whereby the first substrate-side bonding structures are treated with the first plasma jet at least prior to bonding the first semiconductor package to the first packaging substrate.

14. The method of claim 13, further comprising bringing the second solder material portions onto, or in proximity to, the second substrate-side bonding structures while the at least one second plasma jet is directed to the second solder material portions, whereby the second substrate-side bonding structures are treated with the second plasma jet at least prior to bonding the second semiconductor package to the second packaging substrate.

15. The method of claim 12, wherein:
each of the at least one first plasma jet and the at least one second plasma jet is generated by a plurality of plasma treatment systems having a respective plasma nozzle that is directed to the first solder material portions or to the second solder material portions during operation; and
one of the plurality of plasma treatment systems is disposed over an assembly of the first semiconductor package and the first packaging substrate during the second plasma package-treatment process on the second semiconductor package with an areal overlap with the first packaging substrate along a vertical direction.

16. An apparatus for forming a bonded assembly, the apparatus comprising:
a process chamber including chamber enclosure and an ambient control system configured to provide a low-oxygen ambient having an oxygen partial pressure that is lower than 17 kPa;
a stage located in the process chamber and configured to hold at least one packaging substrate thereupon;
a thermocompressive bonding head located in the process chamber and configured to hold and carry a semiconductor package over a stage, and to induce reflow of solder material portions on the semiconductor package;
at least one plasma treatment system located within the process chamber and configured to generate a respective plasma jet along a respective direction toward the solder material portions;
a first transport system configured to transport the thermocompressive bonding head and the semiconductor package toward the stage; and
a process controller configured to operate the at least one plasma treatment system such that the respective plasma jet is generated while the semiconductor package is transported toward the stage.

17. The apparatus of claim 16, further comprising a second transport system configured to transport the at least one plasma treatment system at a same speed as the semiconductor package while the semiconductor package is transported toward the stage.

18. The apparatus of claim 16, wherein:
at least one plasma treatment system comprises a respective plasma nozzle; and
each plasma nozzle of the at least one first plasma treatment system changes a respective nozzle direction such that the respective plasma jet is directed at the solder material portions while the semiconductor package is transported toward the stage.

19. The apparatus of claim 16, wherein the process controller configured to operate the at least one plasma treatment system such that the respective plasma jet is directed toward a surface of one of the at least one packaging substrate on the stage after the semiconductor package is transported to a bonding position overlying the one of the at least one packaging substrate.

20. The apparatus of claim 16, wherein the apparatus is free of any flux material within a volume of the process chamber, and does not include any conduit for flowing any flux material therein or thereupon.
